(19) United States
(12) Patent Application Publication
(10) Pub. No.: US 2026/0255490 A1
(43) Pub. Date: Aug. 27, 2026

(54) PRINTED CIRCUIT BOARD

(71) Applicant: SAMSUNG ELECTRO-MECHANICS CO., LTD., Suwon-si (KR)

(72) Inventors: Ho In JUN, Suwon-si (KR); Jung Eun LEE, Suwon-si (KR); Jin Hwan KIM, Suwon-si (KR)

(73) Assignee: SAMSUNG ELECTRO-MECHANICS CO., LTD., Suwon-si (KR)

(21) Appl. No.: 19/442,097

(22) Filed: Jan. 7, 2026

(30) Foreign Application Priority Data
Feb. 27, 2025 (KR) 10-2025-0025624

(51) Int. Cl. H05K 1/16; H05K 1/11; H05K 3/40

(52) U.S. Cl. CPC H05K 1/162; H05K 1/115; H05K 3/4038; H05K 2201/09827

(57) ABSTRACT

A printed circuit board includes a first insulating layer with a through-hole and a capacitor disposed along a side surface of the through-hole. The capacitor has first and second electrode layers arranged with a dielectric layer between them. A first interconnection layer is positioned on an upper side of the through-hole and includes first and second metal layers respectively contacting the first and second electrode layers. Portions of the first and second metal layers are removed to form cut-out regions that facilitate electrical routing while maintaining the layered capacitor structure within the through-hole.

This application claims the benefit of priority to Korean Patent Application No. 10-2025-0025624 filed on Feb. 27, 2025, with the Korean Intellectual Property Office, the disclosure of which is incorporated herein by reference in its entirety.

### TECHNICAL FIELD

The present disclosure relates to a printed circuit board.

Conventionally, a structure in which passive elements such as chip capacitors and silicon capacitors have been mounted outside of a printed circuit board (PCB), or passive elements are embedded after forming a cavity in a core of the PCB has been adopted.

However, when a plurality of passive elements are mounted on the outside of the PCB, a plurality of passive elements may occupy an external area of the PCB, and thus space efficiency of the PCB may be degraded.

Furthermore, when a cavity for embedding a passive element is formed in the core of the PCB, there is a disadvantage in that a separate cavitation processing space should be secured, and the passive element may only be embedded inside a limited space of the PCB. In addition, there is a concern that the dispersion of an insulating thickness may be reduced by a cavity asymmetrically occupying the inner volume of the PCB.

### SUMMARY

One aspect of the present disclosure is to provide a printed circuit board having excellent integration.

One aspect of the present disclosure is to provide a printed circuit board having excellent reliability.

One aspect of the present disclosure is to provide a printed circuit board that may omit cavity processing and embedding processes by introducing a via capacitor.

However, the aspects of the present disclosure are not limited to the above-described contents, and may be more easily understood in the process of describing specific embodiments of the present disclosure.

A printed circuit board according to an example embodiment of the present disclosure may include: a first insulating layer; a through-hole penetrating through at least a portion of the first insulating layer; a capacitor including a first electrode layer disposed on a side surface of the through-hole, a second electrode layer disposed on a side surface of the first electrode layer, and a first dielectric layer disposed between the first and second electrode layers; and a first interconnection layer including a first metal layer covering an upper surface of the first electrode layer, and a second metal layer covering an upper surface of the second electrode layer, and the first and second metal layers may have first and second cut-out portions, respectively.

A printed circuit board according to an example embodiment of the present disclosure may include: a first insulating layer having a through-hole; a capacitor including a first electrode layer, a first dielectric layer and a second electrode layer sequentially disposed on a side surface of the through-hole; and first and second metal layers disposed on an upper side of the through-hole and connected to the first and second electrode layers, respectively, and when viewed from the upper side of the through-hole, each of the first and second metal layers may have a shape corresponding to the first and second electrode layers, respectively, and the first and second metal layers may include first and second cut-out portions that are open in different directions, respectively.

One effect of the present disclosure is to provide a printed circuit board having excellent integration.

One effect of the present disclosure is to provide a printed circuit board having excellent reliability.

One effect of the present disclosure is to provide a printed circuit board that may omit cavity processing and embedding processes by introducing a via capacitor.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system.

FIG. 2 is a perspective view schematically illustrating an example of an electronic device.

FIG. 3 is a top plan view schematically illustrating a printed circuit board according to an example embodiment of the present disclosure.

FIG. 4 is a cross-sectional view schematically illustrating a cross-section taken along line I-I’ of FIG. 3.

FIG. 5 is a cross-sectional view schematically illustrating a cross-section taken along line II-II’ of FIG. 3.

FIG. 6 is a cross-sectional view schematically illustrating a cross-section taken along line III-III’ of FIG. 4.

FIG. 7 is a perspective view schematically illustrating a first interconnection layer of a printed circuit board according to an example embodiment of the present disclosure.

FIGS. 8A to 8H are cross-sectional views and/or top plan views corresponding to FIG. 5, for the purpose of illustrating an example of a method of manufacturing the printed circuit board of FIGS. 3 to 5.

FIG. 9 is a top plan view schematically illustrating a printed circuit board according to another example embodiment of the present disclosure.

FIG. 10 is a schematic cross-sectional view taken along line IV-IV’ of FIG. 9.

FIG. 11 is a schematic cross-sectional view taken along line V-V’ of FIG. 9; and

FIGS. 12A to 12G are cross-sectional views and/or top plan views corresponding to FIG. 11, for the purpose of illustrating an example of a method of manufacturing the printed circuit board of FIGS. 9 to 11.

### DETAILED DESCRIPTION

Hereinafter, example embodiments of the present disclosure will be described with reference to specific examples and the attached drawings. However, the example embodiments of the present disclosure may be modified to have various other forms, and the scope of the present disclosure is not limited to the example embodiments described below. Furthermore, the example embodiments of the present disclosure are provided to more completely explain the present disclosure to those skilled in the art. Accordingly, the shapes and sizes of elements in the drawings may be exaggerated for clearer description, and elements indicated by the same reference numerals in the drawings are the same elements.

Furthermore, in order to clearly describe the present disclosure in the drawings, contents unrelated to the description are omitted, and since sizes and thicknesses of each component illustrated in the drawings are arbitrarily illustrated for convenience of description, the present disclosure is not limited thereto. Furthermore, components with the same function within the same range of ideas are described using the same reference numerals. Throughout the specification, when a certain portion “includes” or “comprises” a certain component, this indicates that other components are not excluded and may be further included unless otherwise noted.

### Electronic Device

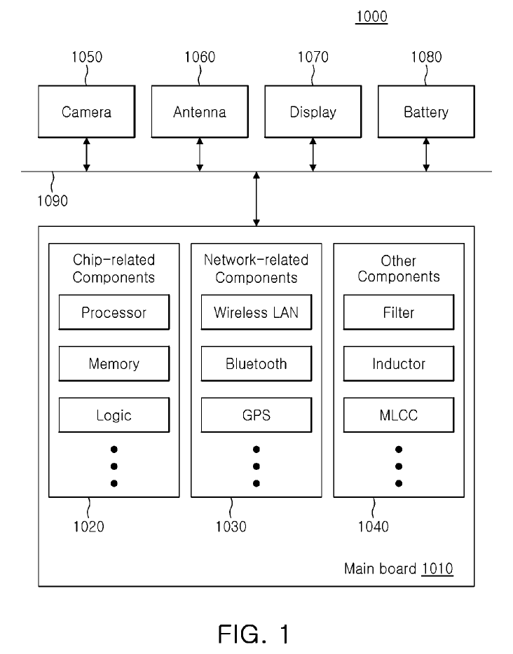

FIG. 1 is a block diagram schematically illustrating an example of an electronic device system.

Referring to FIG. 1, an electronic device 1000 accommodates a main board 1010. Chip-related components 1020, network-related components 1030, and other components 1040 are physically and/or electrically connected to the main board 1010. These components are also coupled to other electronic components to be described below, thus forming various signal lines 1090.

The chip-related components 1020 may include: memory chips such as a volatile memory (e.g., a DRAM), a non-volatile memory (e.g., ROM), and a flash memory; application processor chips such as a central processor (e.g., CPU), a graphics processor (e.g., a GPU), a digital signal processor, a cryptographic processor, a microprocessor, or a microcontroller; and logic chips such as analog-to-digital converters and application-specific IC (ASIC), but the present disclosure is not limited thereto, and other types of chip-related electronic components may also be included. Furthermore, the chip-related components 1020 may be combined with each other. The chip-related components 1020 may also be in the form of a package including the above-described chips or electronic components.

The network-related components 1030 may include Wi-Fi (e.g., IEEE 802.11 family), WiMAX (e.g., IEEE 802.16 family), IEEE 802.20, LTE (long term evolution), Ev-DO, HSPA+, HSDPA+, HSUPA+, EDGE, GSM, GPS, GPRS, CDMA, TDMA, DECT, Bluetooth, 3G, 4G, 5G, and any other wireless and wired protocols designated thereafter, but the present disclosure is not limited thereto, and the network-related components 1030 may include any of numerous other wireless or wired standards or protocols. Furthermore, the network-related components 1030 may be coupled to the chip-related components 1020.

Other components 1040 include a high-frequency inductor, a ferrite inductor, a power inductor, a ferrite bead, low-temperature co-firing ceramics (LTCC), electromagnetic interference (EMI) filters, and multi-layer ceramic capacitors (MLCC). However, the present disclosure is not limited thereto, and may also include passive components in the form of chip components used for various other purposes. Furthermore, other components 1040 may be coupled to the chip-related components 1020 and/or the network-related components 1030.

Depending on the type of electronic device 1000, the electronic device 1000 may include other electronic components that may or may not be physically and/or electrically connected to the main board 1010. Examples of other electronic components include a camera 1050, an antenna 1060, a display 1070, and a battery 1080. However, the present disclosure is not limited thereto, and the electronic device 1000 may also include an audio codec, a video codec, a power amplifier, a compass, an accelerometer, a gyroscope, a speaker, a mass storage device (e.g., a hard disk drive), a compact disc (CD), and a digital versatile disk (DVD). Furthermore, other electronic components used for various purposes may also be included depending on the type of electronic device 1000.

The electronic device 1000 may be a smartphone, a personal digital assistant, a digital video camera, a digital still camera, a network system, a computer, a monitor, a tablet, a laptop, a netbook, a television, a video game device, a smart watch, an automotive device, or the like. However, the present disclosure is not limited thereto, and the electronic device 1000 may also be any other electronic device capable of processing data.

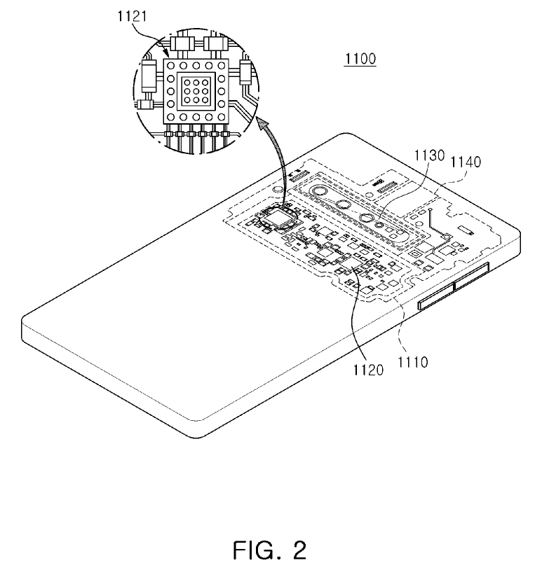

FIG. 2 is a perspective view schematically illustrating an example of an electronic device.

Referring to FIG. 2, the electronic device may be, for example, a smartphone 1100. A motherboard 1110 is accommodated in the smartphone 1100, and various components 1120 are physically and/or electrically connected to the motherboard 1110. Additionally, other components that may or may not be physically and/or electrically connected to the motherboard 1110, such as the camera module 1130 and/or the speaker 1140, are accommodated therein. Some of the components 1120 may be the above-described chip-related components, for example, a component package 1121, but the present disclosure is not limited thereto. The component package 1121 may be a printed circuit board (PCB) on which electronic components, including active and/or passive components, are surface-mounted. Alternatively, the component package 1121 may be a PCB incorporating active and/or passive components. Meanwhile, the electronic device is not necessarily limited to the smartphone 1100, and may also be other electronic devices, as described above.

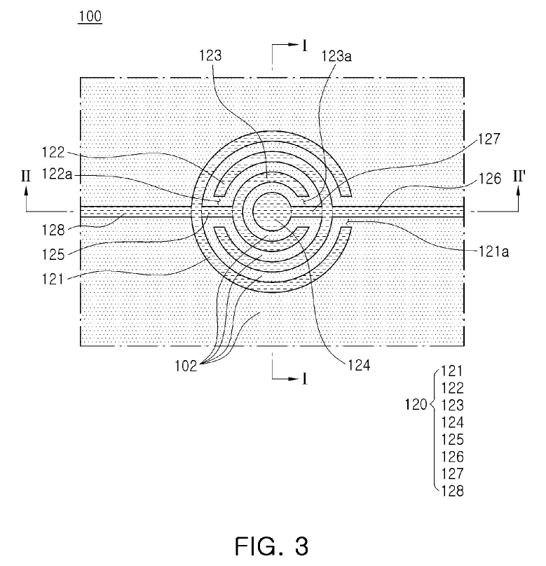

FIG. 3 is a top plan view schematically illustrating a printed circuit board according to an example embodiment of the present disclosure.

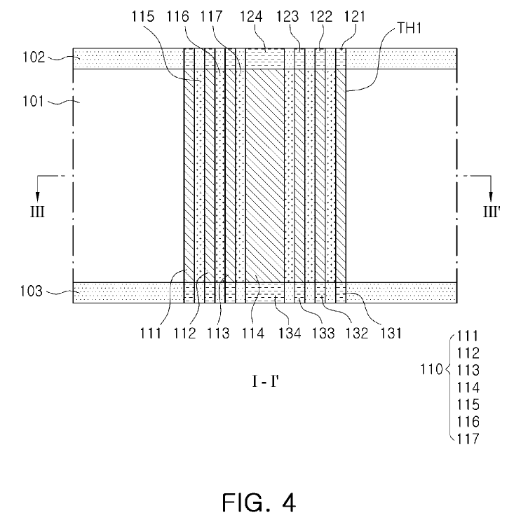

FIG. 4 is a cross-sectional view schematically illustrating a cross-section taken along line I-I’ of FIG. 3.

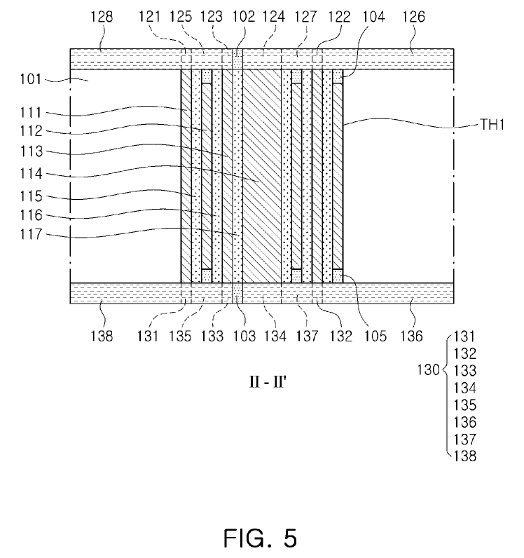

FIG. 5 is a cross-sectional view schematically illustrating a cross-section taken along line II-II’ of FIG. 3.

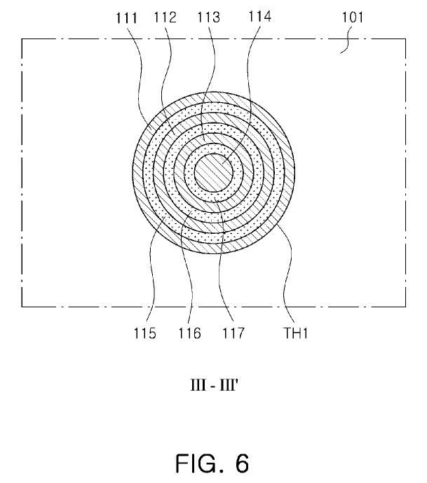

FIG. 6 is a cross-sectional view schematically illustrating a cross-section taken along line III-III’ of FIG. 4.

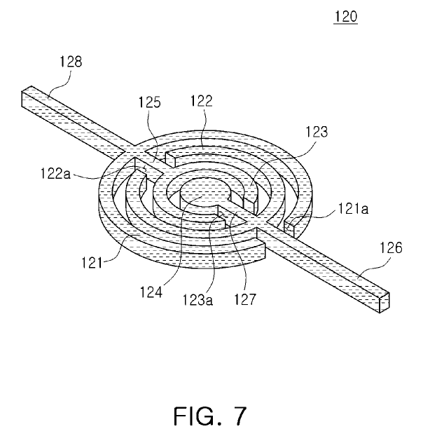

FIG. 7 is a perspective view schematically illustrating a first interconnection layer of a printed circuit board according to an example embodiment of the present disclosure.

Referring to FIGS. 3 to 7, a printed circuit board 100 may include a first insulating layer 101 having a through-hole TH1, a capacitor 110, and a first interconnection layer 120.

The first insulating layer 101 may have a structure in which one or more insulating layers are stacked. The through-hole TH1 may penetrate through at least a portion of the first insulating layer 101. For example, the through-hole TH1 may penetrate between an upper surface and a lower surface of the first insulating layer 101. While the drawing illustrates a structure in which the first insulating layer 101 has one through-hole TH1, the present disclosure is not limited thereto. The first insulating layer 101 may have a plurality of through-holes TH1.

The capacitor 110 may include, for example, a first electrode layer 111 disposed on a side surface of the through-hole TH1, a second electrode layer 112 disposed on a side surface of the first electrode layer 111, and a first dielectric layer 115 disposed between the first and second electrode layers 111 and 112. The capacitor 110 may include, for example, a first electrode layer 111, a first dielectric layer 115, and a second electrode layer 112 sequentially disposed on the side of the through-hole TH1.

The first electrode layer 111 and the second electrode layer 112 may be disposed to face each other with the first dielectric layer 115 interposed therebetween, thereby forming electrostatic capacitance. The capacitor 110 may function as an electronic device that charges voltage and outputs current by utilizing the characteristic of repeated charging and discharging. This may stabilize unstable power and may eliminate noise. This may also block direct current and may pass alternating current. Furthermore, the capacitor 110 may be used for the stable operation of semiconductor chips.

Other methods of disposing a capacitor on a printed circuit board include a method of mounting chip capacitors, such as MLCCs, on a surface of the printed circuit board, or forming a separate cavity on the printed circuit board and embedding a chip capacitor in the cavity.

However, in the case of mounting a plurality of chip capacitors on the surface of a printed circuit board, the chip capacitors may occupy an outer surface area of the printed circuit board to cause the space efficiency of the printed circuit board to be reduced. Furthermore, when mounting the chip capacitors to the surface of a printed circuit board via soldering, there may be a concern of occurrence of cracking in the chip capacitor or detachment of the chip capacitor due to surface tension of the soldering, and there may be a concern of increased parasitic inductance due to the soldering connection. In contrast, the printed circuit board 100 according to an example embodiment of the present disclosure may include a capacitor 110 disposed within the through-hole TH1 to reduce the number of chip capacitors mounted on a surface of the printed circuit board 100, thereby improving the integration density of the printed circuit board 100. Furthermore, the capacitor 110 may be disposed within the through-hole TH1 to have enhanced reliability, and may be directly connected within a signal path of the printed circuit board 100 to improve signal integrity (SI) characteristics and reduce parasitic inductance.

Meanwhile, when embedding a chip capacitor within a cavity of the printed circuit board, separate cavity processing and embedding processes should be performed, and the cavity may asymmetrically occupy an internal volume of the printed circuit board, which may reduce the dispersion of the insulation thickness of the printed circuit board. Furthermore, since the chip capacitor embedded in the cavity should be connected to other components through the interconnection layer formed within the printed circuit board, parasitic inductance may occur and the chip capacitor may only be embedded within the limited space of the cavity. In contrast, the printed circuit board 100 according to an example embodiment of the present disclosure may omit separate cavity processing and embedding processes, and the cavity may be omitted to improve reliability characteristics such as insulation thickness distribution and warpage characteristics of the printed circuit board 100. Furthermore, the capacitor 110 of the printed circuit board 100 according to an example embodiment of the present disclosure may be directly connected within the signal path, so that parasitic inductance may be reduced, and a number of through-holes TH1 may be formed as required in the printed circuit board 100 and the capacitors 110 may disposed therein, so that the integration density of the printed circuit board 100 may be improved.

The first interconnection layer 120 may include, for example, a first metal layer 121 covering an upper surface of the first electrode layer 111 and a second metal layer 122 covering an upper surface of the second electrode layer 112. For example, the first and second metal layers 121 and 122 may be disposed on an upper side of the through-hole TH1 and connected to the first and second electrode layers 111 and 112, respectively.

The first and second metal layers 121 and 122 may include first and second cut-out portions 121a and 122a, respectively. For example, when viewed from the upper side of the through-hole TH1, the first and second metal layers 121 and 122 may have shapes corresponding to the first and second electrode layers 111 and 112, respectively, but the first and second metal layers 121 and 122 may include first and second cut-out portions 121a and 122a that are open in different directions, respectively. That is, each of the first and second metal layers 121 and 122 may have a ring shape in which a portion thereof is cut off by the first and second cut-out portions 121a and 122a.

For example, the first cut-out portion 121a may be open in a first direction, and the second cut-out portion 122a may be open in a second direction, different from the first direction. The first and second directions are not particularly limited, but may be opposite directions. For example, the first direction may be a rightward direction in FIG. 3, and the second direction may be a leftward direction in FIG. 3.

The first and second cut-out portions 121a and 122a may be configured to connect the first metal layer 121 and the second metal layer 122, which have different polarities, to signal patterns of the first interconnection layer 120, which have different polarities. For example, the first interconnection layer 120 may include a first conductor layer 125 penetrating through the second cut-out portion 122a and connected to the first metal layer 121, and a second conductor layer 126 penetrating through the first cut-out portion 121a and connected to the second metal layer 122. That is, the first and second conductor layers 125 and 126 may be spaced apart from the second and first metal layers 122 and 121, respectively, through the first and second cut-out portions 121a and 122a.

In an example embodiment, the capacitor 110 may further include: a third electrode layer 113 disposed on a side surface of the second electrode layer 112, a second dielectric layer 116 disposed between the second and third electrode layers 112 and 113, a fourth electrode layer 114 disposed on a side surface of the third electrode layer 113, and a third dielectric layer 117 disposed between the third and fourth electrode layers 113 and 114. That is, the capacitor 110 may include the first electrode layer 111, the first dielectric layer 115, the second electrode layer 112, the second dielectric layer 116, the third electrode layer 113, and the third dielectric layer 117 sequentially disposed on the side surface of the through-hole TH1, and may include a fourth electrode layer 114 disposed on a side surface of the third dielectric layer 117 to fill a central portion of the through-hole TH1. The electrode layers 111, 112, 113 and 114 and the dielectric layers 115, 116 and 117 may be alternately disposed in a direction oriented from the center of the through-hole TH1 toward the side surface of the through-hole TH1. The first to third electrode layers 111, 112 and 113 and the first to third dielectric layers 115, 116 and 117 may have hollow column shapes, and the fourth electrode layer 114 may have column shapes.

The first interconnection layer 120 may include a third metal layer 123 covering an upper surface of the third electrode layer 113 and a fourth metal layer 124 covering an upper surface of the fourth electrode layer 114. For example, the third and fourth metal layers 123 and 124 may be disposed on an upper side of the through-hole TH1 and may be connected to the third and fourth electrode layers 113 and 114, respectively.

The third metal layer 123 may have a third cut-out portion 123a. For example, when viewed from the upper side of the through-hole TH1, the third metal layer 123 may have a shape corresponding to the third electrode layer 113, but may include the third cut-out portion 123a. That is, the third metal layer 123 may have a ring shape in which a portion thereof is cut off by the third cut-out portion 123a. For example, each of the first and third cut-out portions 121a and 123a may be open in the first direction, and the second cut-out portion 122a may be open in the second direction, which is different from the first direction.

The first interconnection layer 120 may include, for example, a first conductor layer 125 penetrating through the second cut-out portion 122a and connected to the first and third metal layers 121 and 123, respectively, a second conductor layer 126 penetrating through the first cut-out portion 121a and connected to the second metal layer 122, and a third conductor layer 127 penetrating through the third cut-out portion 123a and connected to the second and fourth metal layers 122 and 124, respectively.

The first conductor layer 125 may be connected to the first metal layer 121 and the third metal layer 123 through the second cut-out portion 122a, respectively, and the first conductor layer 125 may be spaced apart from the second metal layer 122. Additionally, the third conductor layer 127 may be connected to the second metal layer 122 and the fourth metal layer 124 through the third cut-out portion 123a, respectively, and the third conductor layer 127 may be spaced apart from the first metal layer 121.

In an example embodiment, the first interconnection layer 120 may further include a fourth conductor layer 128 connected to an outer surface of the first metal layer 121. The first conductor layer 125 and the fourth conductor layer 128 may be arranged parallel to each other, and the second conductor layer 126 and the third conductor layer 127 may be arranged parallel to each other, but the present disclosure is not limited thereto. The first conductor layer 125 and the fourth conductor layer 128 may form first traces connected to the first metal layer 121 and the third metal layer 123, respectively, and the second conductor layer 126 and the third conductor layer 127 may form second traces connected to the second metal layer 122 and the fourth metal layer 124, respectively. The first electrode layer 111 and the third electrode layer 113, which have the same polarity, may be connected in parallel through the first conductor layer 125 and the fourth conductor layer 128, and the second electrode layer 112 and the fourth electrode layer 114, which have the same polarity, may be connected in parallel through the second conductor layer 126 and the third conductor layer 127.

In an example embodiment, a first insulating film 104 may be further disposed between the first cut portion 121a and the first electrode layer 111, and between the second cut portion 122a and the second electrode layer 112. The first insulating film 104 may also be disposed between the third cut portion 123a and the third electrode layer 113. The first insulating film 104 may electrically isolate the first conductor layer 125 and the second electrode layer 112 having different polarities, may electrically isolate the second conductor layer 126 and the first electrode layer 111, and may electrically isolate the third conductor layer 127 and the third electrode layer 113. The first insulating film 104 may include the same insulating material as the first insulating layer 101 or may include a different insulating material from the first insulating layer 101.

The printed circuit board 100 may further include a second insulating layer 102 disposed on an upper surface of the first insulating layer 101. The second insulating layer 102 may include the same insulating material as the first insulating layer 101 or may include a different insulating material from the first insulating layer 101.

In an example embodiment, at least a portion of the first interconnection layer 120 may be embedded in the second insulating layer 102. An upper surface of the first interconnection layer 120 and an upper surface of the second insulating layer 102 may be substantially coplanar with each other, and a lower surface of the first interconnection layer 120 and a lower surface of the second insulating layer 102 may be substantially coplanar with each other, but the present disclosure is not limited thereto. The first interconnection layer 120 may be embedded in the second insulating layer 102, thereby easily reducing an overall thickness of the printed circuit board 100.

The printed circuit board 100 may further include a second interconnection layer 130 including a fifth metal layer 131 covering a lower surface of the first electrode layer 111 and a sixth metal layer 132 covering a lower surface of the second electrode layer 112. The second interconnection layer 130 may further include, for example, a seventh metal layer 133 covering a lower surface of the third electrode layer 113 and an eighth metal layer 134 covering a lower surface of the fourth electrode layer 114.

The second interconnection layer 130 may have a shape that is symmetrical with respect to the first interconnection layer 120 in a thickness direction of the printed circuit board 100. That is, although not illustrated, the fifth through seventh metal layers 131, 132 and 133 may include fourth through sixth cut-out portions, respectively. The second interconnection layer 130 may include, for example, a fifth conductor layer 135 penetrating through the fifth cut-out portion and connected to the fifth and seventh metal layers 131 and 133, respectively, a sixth conductor layer 136 penetrating through the fourth cut-out portion and connected to the sixth metal layer 132, and a seventh conductor layer 137 penetrating through the sixth cut-out portion and connected to the sixth and eighth metal layers 132 and 134, respectively. The second interconnection layer 130 may further include an eighth conductor layer 138 connected to an outer surface of the fifth metal layer 131. The fifth conductor layer 135 and the eighth conductor layer 138 may form third traces connected to the fifth metal layer 131 and the seventh metal layer 133, respectively, and the sixth conductor layer 136 and the seventh conductor layer 137 may form fourth traces connected to the sixth metal layer 132 and the eighth metal layer 134, respectively.

Furthermore, a second insulating film 105 may be further disposed between the fourth cut-out portion and the first electrode layer 111, and between the fifth cut-out portion and the second electrode layer 112. The second insulating film 105 may also be disposed between the sixth cut-out portion and the third electrode layer 113. The second insulating film 105 may include the same insulating material as the first insulating layer 101, or may include a different insulating material from the first insulating layer 101.

The printed circuit board 100 may further include a third insulating layer 103 disposed on a lower surface of the first insulating layer 101. The third insulating layer 103 may include the same insulating material as the first insulating layer 101, or may include a different insulating material.

In an example embodiment, at least a portion of the second interconnection layer 130 may be embedded in the third insulating layer 103. An upper surface of the second interconnection layer 130 and an upper surface of the third insulating layer 103 may be substantially coplanar with each other, and a lower surface of the second interconnection layer 130 and a lower surface of the third insulating layer 103 may be substantially coplanar with each other. However, the present disclosure is not limited thereto. The second interconnection layer 130 may be embedded in the third insulating layer 103, thereby easily reducing an overall thickness of the printed circuit board 100.

Hereinafter, each component included in the printed circuit board 100 will be described in more detail.

Each of the first, second, and third insulating layers 101, 102 and 103 may include an insulating material. The insulating material may include a thermosetting resin such as epoxy resin, a thermoplastic resin such as polyimide, or inorganic fillers, organic fillers and/or glass fibers (Glass Fiber, Glass Cloth, and/or Glass Fabric) along with such resins. The insulating material may include a photosensitive material and/or a non-photosensitive material. For example, as the insulating materials for the first, second and third insulating layers 101, 102 and 103, Prepreg (PPG) and Resin Coated Copper (RCC) may be used, but the present disclosure is not limited thereto, and an Ajinomoto Build-up Film (ABF), Photo Imageable Dielectric (PID), FR-4 and Bismaleimide Triazine (BT) may also be used. Furthermore, other polymeric materials having excellent rigidity may be used as the insulating materials for the first, second and third insulating layers 101, 102 and 103.

Each of the first to fourth electrode layers 111, 112, 113 and 114 may include a metal material. The metal material included in the first to fourth electrode layers 111, 112, 113 and 114 may include, for example, one or more of Cu, Al, Ag, Sn, Au, Ni, Pb, Ti, and alloys thereof. Each of the first to fourth electrode layers 111, 112, 113 and 114 may include an electroless plating layer (or chemical copper) as a seed layer and an electrolytic plating layer (or electrolytic copper) as a plating layer. However, the present disclosure is not limited thereto. Instead of an electroless plating layer, a sputtering layer may be formed as the seed layer.

The first to third dielectric layers 115, 116, and 117 may include a dielectric material, different from the insulating material included in the first insulating layer 101. For example, each of the first to third dielectric layers 115, 116, and 117 may include a mixture of dielectric particles and a resin. Each of the first to third dielectric layers 115, 116 and 117 may have dielectric particles dispersed in the resin, but the present disclosure is not limited thereto. The dielectric particles may include one or more of alumina, silica, silicon nitride, tantalum oxide, titanium oxide, calcium titanate, barium titanate, and strontium titanate particles, depending on insulating properties or relative permittivity. A resin included in the first to third dielectric layers 115, 116 and 117 may include an organic polymer insulating material, but the present disclosure is not limited thereto.

Each of the first and second interconnection layers 120 and 130 may include a metal material. The metal material included in the first and second interconnection layers 120 and 130 may include, for example, one or more of Cu, Al, Ag, Sn, Au, Ni, Pb, Ti, and alloys thereof. Each of the first and second interconnection layers 120 and 130 may include an electroless plating layer (or chemical copper) as a seed layer, and an electrolytic plating layer (or electrolytic copper) as a plating layer, but the present disclosure is not limited thereto. Instead of an electroless plating layer, a sputtering layer may be formed as the seed layer. If necessary, a copper foil may be further included.

Each of the first and second interconnection layers 120 and 130 may perform various functions depending on the design. For example, each of the first and second interconnection layers 120 and 130 may include signal patterns, power patterns, and ground patterns, and each of these patterns may have various shapes, such as lines (or traces), planes (or plates), and pads (or lands).

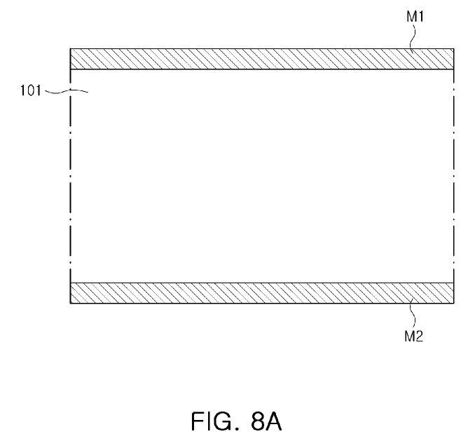

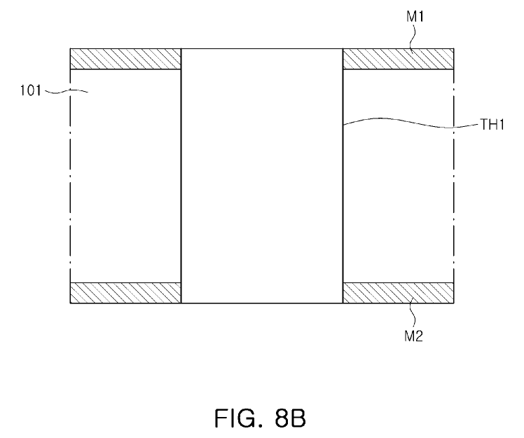

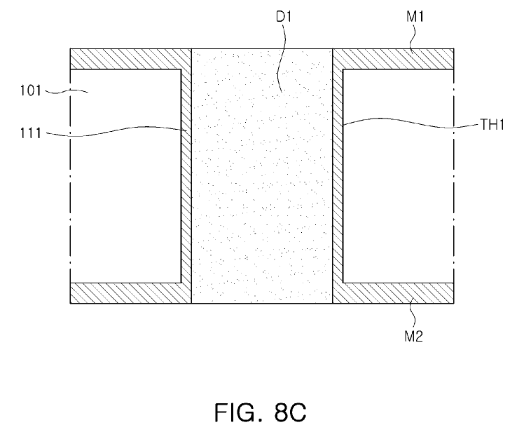

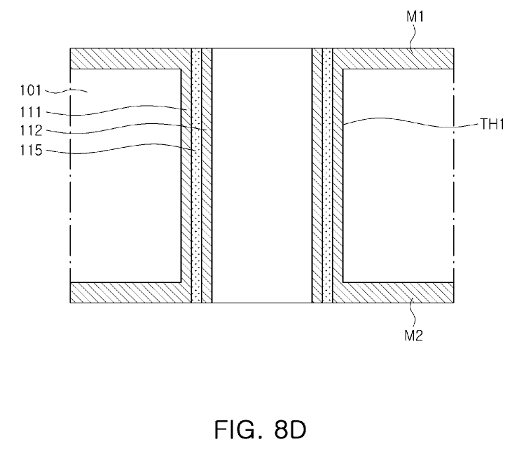

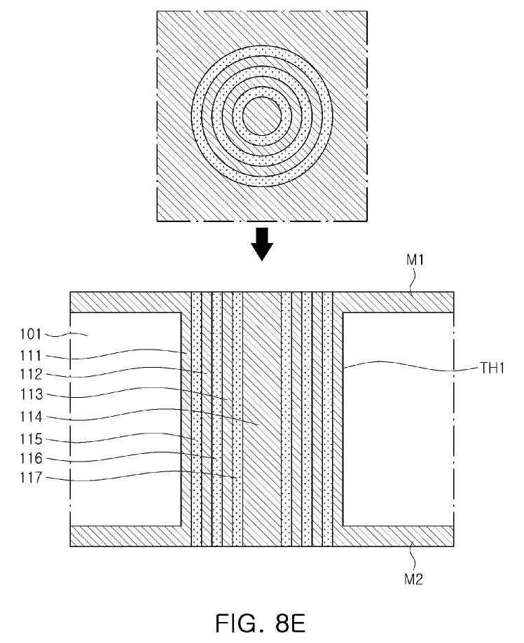

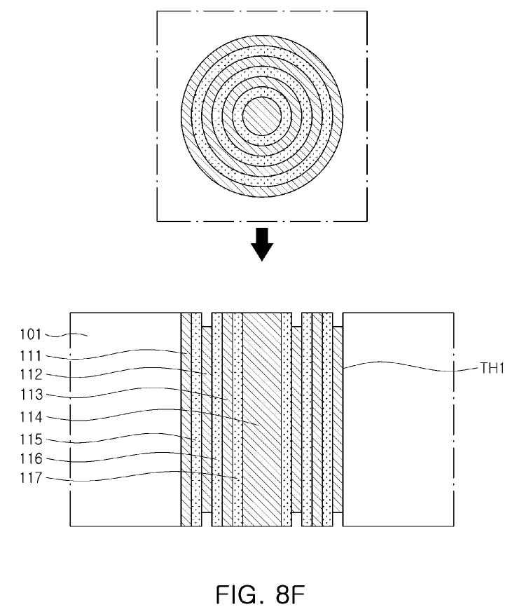

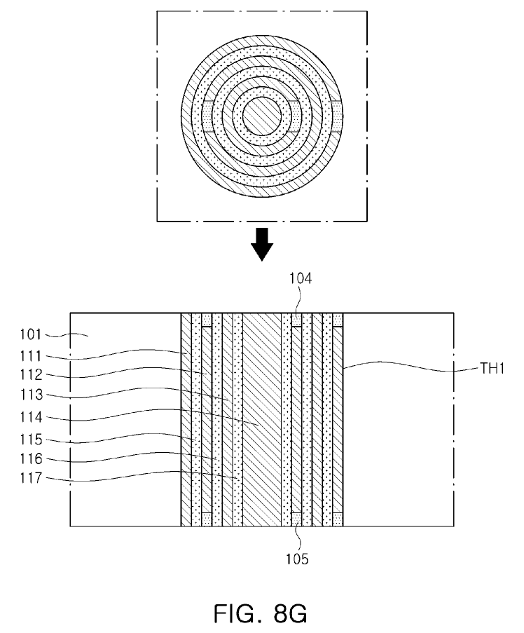

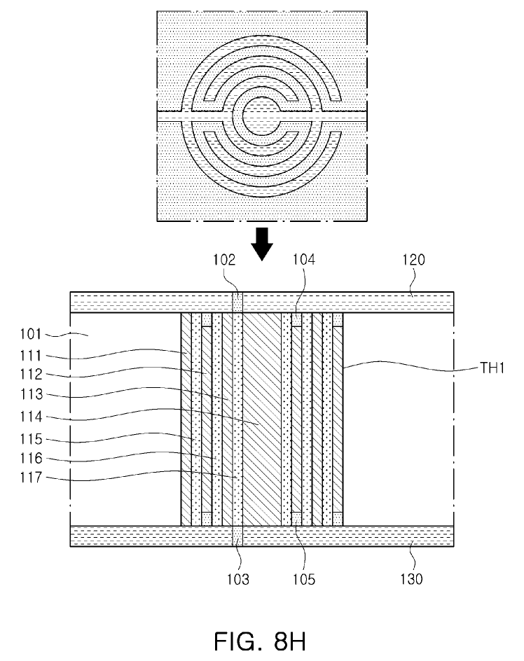

FIGS. 8A to 8H are cross-sectional views and/or top plan views corresponding to FIG. 5, for the purpose of illustrating an example of a method of manufacturing the printed circuit board of FIGS. 3 to 5.

Hereinafter, with reference to FIGS. 8A to 8H, an example of a method of manufacturing a printed circuit board 100 will be described, but the present disclosure is not limited thereto.

Referring to FIG. 8A, after preparing the first insulating layer 101, first and second metal thin film layers M1 and M2 may be formed on upper and lower surfaces of the first insulating layer 101, respectively. The metal thin film layers M1 and M2 may be formed, for example, by electroless plating, such as chemical copper plating. If necessary, the metal thin film layers M1 and M2 may also be formed by sputtering.

Referring to FIG. 8B, a through-hole TH1 may be formed in the first insulating layer 101 on which the metal thin film layers M1 and M2 are formed. The through-hole TH1 may be formed, for example, by mechanical drilling.

Referring to FIG. 8C, a first electrode layer 111 may be formed on a side surface of the through-hole TH1 using electroless plating (chemical copper), electrolytic plating (electrolytic copper), and/or sputtering, and then, an interior of the through-hole TH1 may be filled with a dielectric material D1.

Referring to FIG. 8D, a portion of the dielectric material D1 may be removed using a method such as drilling to form the first dielectric layer 115. Next, a second electrode layer 112 may be formed on a side surface of the first dielectric layer 115 using electroless plating (chemical copper), electrolytic plating (electrolytic copper), and/or sputtering.

Referring to FIG. 8E, the processes illustrated in FIGS. 8C and 8D may be repeated to sequentially form a second dielectric layer 116, a third electrode layer 113, and a third dielectric layer 117 on the second electrode layer 112. Finally, a fourth electrode layer 114 may be formed in the central portion of the through-hole TH1 using electroless plating (chemical copper), electrolytic plating (electrolytic copper), and/or sputtering. Accordingly, a capacitor 110 may be formed within the through-hole TH1.

Referring to FIG. 8F, an etching process may be performed on the metal thin film layers M1 and M2 and the ends of the first to third electrode layers 111, 112 and 113. Referring to FIG. 8G, first and second insulating films 104 and 105 may be formed in ends of the first to third electrode layers 111, 112 and 113.

Referring to FIG. 8H, a second insulating layer 102 and a first interconnection layer 120 may be formed on an upper surface of the first insulating layer 101, and a third insulating layer 103 and a second interconnection layer 130 may be formed on a lower surface of the first insulating layer 101. The method for forming the second and third insulating layers 102 and 103 and the first and second interconnection layers 120 and 130 is not particularly limited. For example, the second and third insulating layers 102 and 103 may be formed on an upper surface and a lower surface of the first insulating layer 101, respectively. Next, a pattern groove having the same shape as the first and second interconnection layers 120 and 130 may be formed on the second and third insulating layers 102 and 103, respectively, through an etching process using a mask. Finally, the pattern groove may be filled using a plating process to form the first and second interconnection layers 120 and 130.

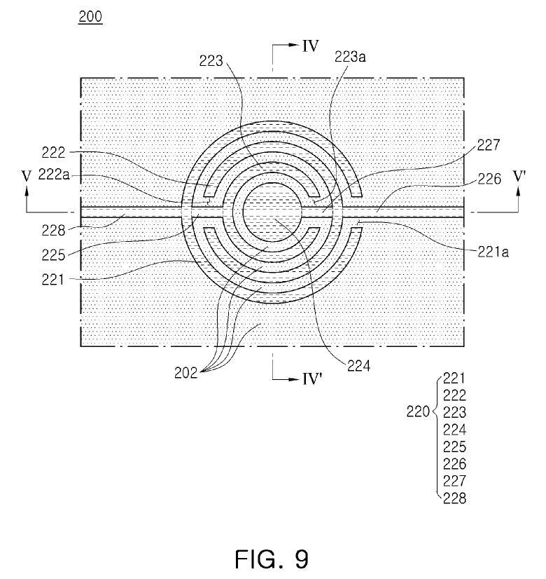

FIG. 9 is a top plan view schematically illustrating a printed circuit board according to another embodiment of the present disclosure.

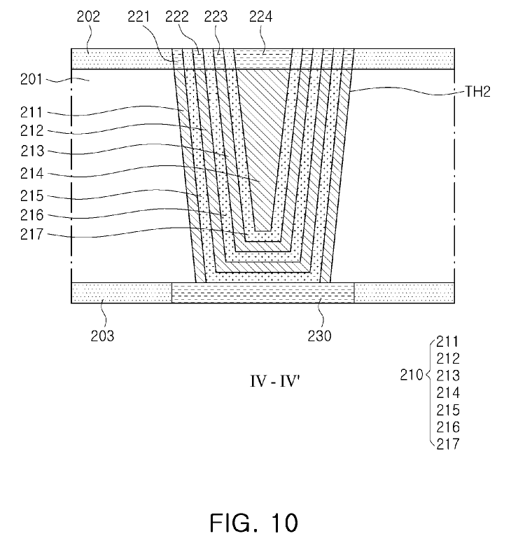

FIG. 10 is a cross-sectional view schematically illustrating a cross-section taken along line IV-IV’ of FIG. 9.

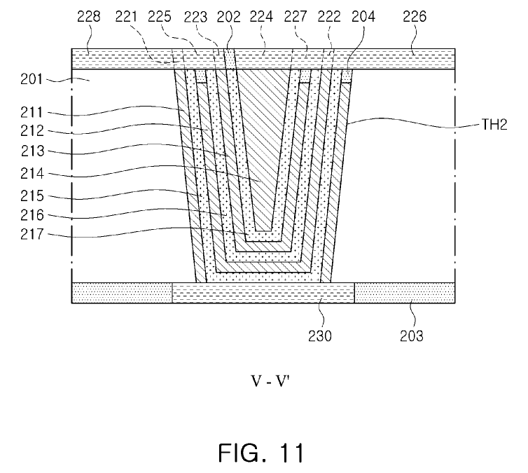

FIG. 11 is a cross-sectional view schematically illustrating a cross-section taken along line V-V’ of FIG. 9.

Hereinafter, a printed circuit board 200 according to another example embodiment of the present disclosure will be described with reference to FIGS. 9 and 11. Components identical or similar to those of the printed circuit board 100 described in FIGS. 3 to 7 are designated by the same or similar reference numerals, and duplicate descriptions will be omitted.

Referring to FIGS. 9 to 11, the printed circuit board 200 may include a first insulating layer 201, a capacitor 210, and a first interconnection layer 220 having a through-hole TH2.

According to an example embodiment of the present disclosure, the through-hole TH2 of the printed circuit board 200 may have a tapered shape so that a width of the upper portion is greater than a width of the lower portion in a cross-sectional view.

The capacitor 210 may include, for example, a first electrode layer 211 disposed on a side surface of the through-hole TH2, a second electrode layer 212 disposed on a side surface of the first electrode layer 211, and a first dielectric layer 215 disposed between the first and second electrode layers 211 and 212. The capacitor 210 may further include a third electrode layer 213 disposed on a side surface of the second electrode layer 212, a second dielectric layer 216 disposed between the second and third electrode layers 212 and 213, a fourth electrode layer 214 disposed on a side surface of the third electrode layer 213, and a third dielectric layer 217 disposed between the third and fourth electrode layers 213 and 214.

The first interconnection layer 220 may include, for example, a first metal layer 221 covering an upper surface of the first electrode layer 211 and a second metal layer 222 covering the upper surface of the second electrode layer 212. The first and second metal layers 221 and 222 may include first and second cut-out portions 221a and 222a, respectively. The first interconnection layer 220 may include a third metal layer 223 covering an upper surface of the third electrode layer 213 and a fourth metal layer 224 covering an upper surface of the fourth electrode layer 214. The third metal layer 223 may have a third cut-out portion 223a.

The first interconnection layer 220 may include a first conductor layer 225 penetrating through the second cut-out portion 222a and connected to the first and third metal layers 221 and 223, a second conductor layer 226 penetrating through the first cut-out portion 221a and connected to the second metal layer 222, and a third conductor layer 227 penetrating through the third cut-out portion 223a and connected to the second and fourth metal layers 222 and 224, respectively. The first interconnection layer 220 may further include a fourth conductor layer 228 connected to the outer surface of the first metal layer 221.

The printed circuit board 200 may further include a second interconnection layer 230 covering a lower surface of the through-hole TH2. In an example embodiment, the first dielectric layer 215 may be continuously disposed on the side surface of the first electrode layer 211 and an upper surface of the second interconnection layer 230. Additionally, the second electrode layer 212 may be continuously disposed on a side surface and a bottom surface of the first dielectric layer 215, the second dielectric layer 216 may be continuously disposed on a side surface and a bottom surface of the second electrode layer 212, the third electrode layer 213 may be continuously disposed on a side surface and a bottom surface of the second dielectric layer 216, and the third dielectric layer 217 may be continuously disposed on a side surface and a bottom surface of the third electrode layer 213. The fourth electrode layer 214 may have a tapered shape so that a width of an upper end thereof is greater than a width of a lower end thereof in cross-section.

The printed circuit board 200 may further include second and third insulating layers 202 and 203 disposed on an upper surface and a lower surface of the first insulating layer 201, respectively. In an example embodiment, at least a portion of the first interconnection layer 220 may be embedded in the second insulating layer 202, and at least a portion of the second interconnection layer 230 may be embedded in the third insulating layer 203. Furthermore, a first insulating film 204 may be further disposed between the first cut-out portion 221a and the first electrode layer 211, and between the second cut-out portion 222a and the second electrode layer 212. The first insulating film 204 may also be disposed between the third cut-out portion 223a and the third electrode layer 213.

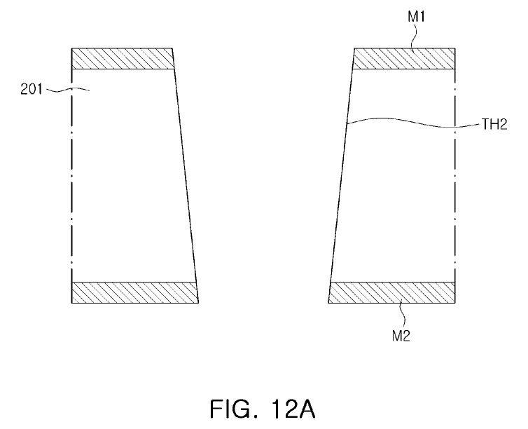

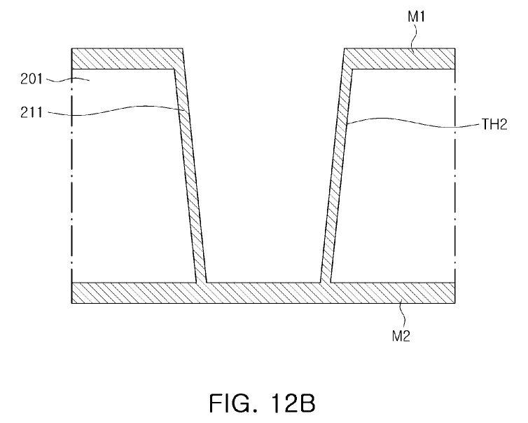

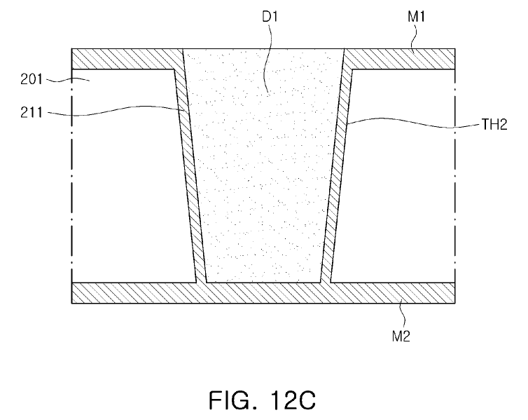

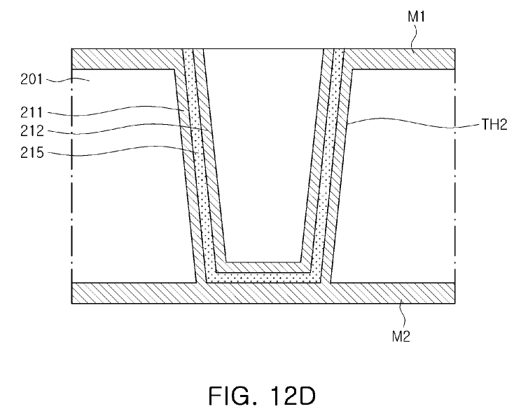

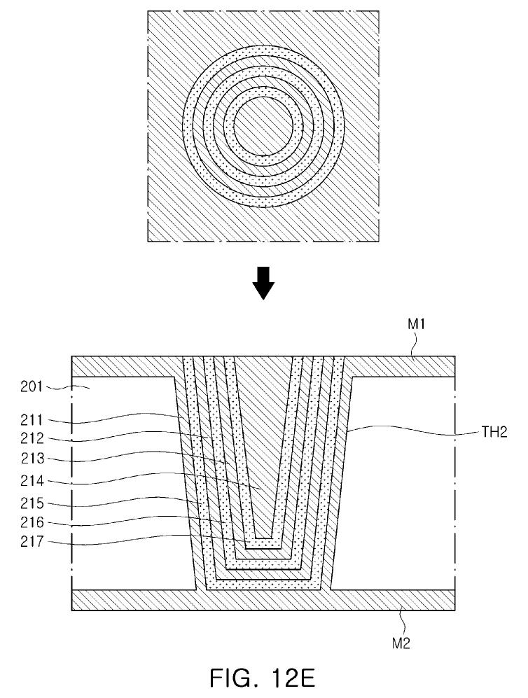

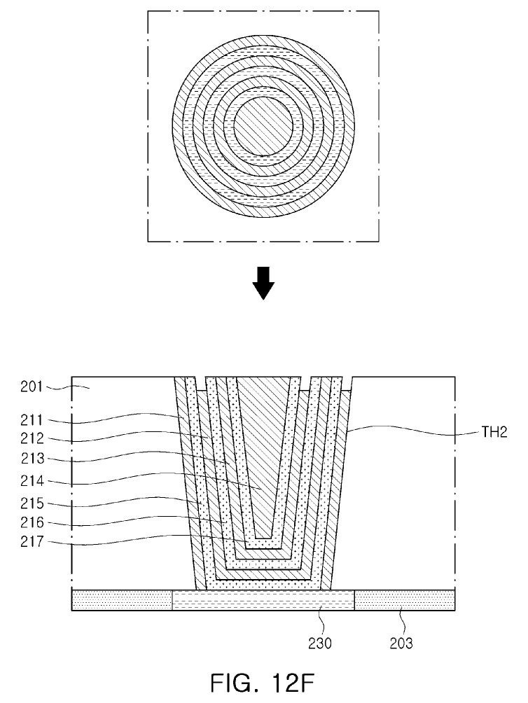

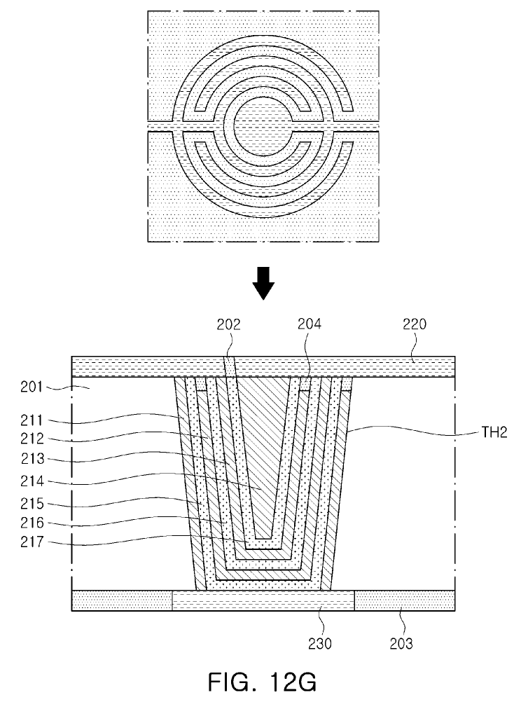

FIGS. 12A to 12G are cross-sectional views and/or top plan views corresponding to FIG. 11, for the purpose of illustrating an example of a method of manufacturing the printed circuit board of FIGS. 9 to 11.

Hereinafter, with reference to FIGS. 12A to 12G, an example of a method of manufacturing a printed circuit board 200 will be described. Components identical or similar to those described in the example of the method of manufacturing the printed circuit board 100 described in FIGS. 8A to 8H are designated by the same or similar reference numerals, and duplicate descriptions are omitted.

Referring to FIG. 12A, a through-hole TH2 may be formed in the first insulating layer 201 on which the first and second metal thin film layers M1 and M2 are formed. The through-hole TH2 may be formed, for example, by laser processing. The through-hole TH2 may have a tapered shape.

Referring to FIG. 12B, a first electrode layer 211 may be formed on a side surface of the through-hole TH2 using electroless plating (chemical copper), electrolytic plating (electrolytic copper), and/or sputtering. In this case, a hole formed in the second metal thin film layer M2 by plating or the like may be filled. Next, referring to FIG. 12C, the interior of the through-hole TH2 may be filled with a dielectric material D1.

Referring to FIG. 12D, a first dielectric layer 215 may be formed by removing a portion of the dielectric material D1 using a method such as laser processing. Next, a second electrode layer 212 may be formed on a side surface and a bottom surface of the first dielectric layer 215 using electroless plating (chemical copper), electrolytic plating (electrolytic copper), and/or sputtering.

Referring to FIG. 12E, by repeating the process, a second dielectric layer 216 may be formed on a side surface and a bottom surface of the second electrode layer 212, a third electrode layer 213 may be formed on a side surface and a bottom surface of the second dielectric layer 216, and a third dielectric layer 217 may be formed on a side surface and a bottom surface of the third electrode layer 213. Finally, a fourth electrode layer 214 may be formed in the central portion of the through-hole TH2 using electroless plating (chemical copper), electrolytic plating (electrolytic copper), and/or sputtering. Accordingly, a capacitor 210 may be formed within the through-hole TH2.

Referring to FIG. 12F, an etching process may be performed on ends of the metal film layers M1 and M2 and the first to third electrode layers 211, 212 and 213. After performing the etching process on the second metal film layer M2, a second insulating layer 203 may be formed in an etched region to form the second interconnection layer 230, but the present disclosure is not limited thereto.

Referring to FIG. 12G, a first insulating film 204 may be formed on the ends of the first to third electrode layers 211, 212 and 213. Next, a second insulating layer 202 and a first interconnection layer 220 may be formed on an upper surface of the first insulating layer 201. The second insulating layer 202 and the first interconnection layer 220 may be formed through an etching process and a plating process using the above-described mask, but, the present disclosure is not limited thereto.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

In addition, the expression ‘an example embodiment’ used in the present disclosure does not denote the same example embodiment, and is provided to emphasize and explain different unique characteristics. However, the example embodiments presented above do not preclude being implemented in combination with the features of another embodiment. For example, although items described in a specific embodiment are not described in another embodiment, the items may be understood as a description related to another embodiment unless a description opposite or contradictory to the items is in another embodiment.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

What is claimed is:

1. A printed circuit board, comprising:
a first insulating layer;
a through-hole penetrating through at least a portion of the first insulating layer;
a capacitor including a first electrode layer disposed on a side surface of the through-hole, a second electrode layer disposed on a side surface of the first electrode layer, and a first dielectric layer disposed between the first and second electrode layers; and
a first interconnection layer including a first metal layer covering an upper surface of the first electrode layer, and a second metal layer covering an upper surface of the second electrode layer,
wherein the first and second metal layers include first and second cut-out portions, respectively.

2. The printed circuit board according to claim 1, wherein the first cut-out portion is open in a first direction, and
the second cut-out portion is open in a second direction, different from the first direction.

3. The printed circuit board according to claim 1, wherein the first interconnection layer further includes a first conductor layer penetrating through the second cut-out portion and connected to the first metal layer, and a second conductor layer penetrating through the first cut-out portion and connected to the second metal layer.

4. The printed circuit board according to claim 1, wherein the capacitor further includes a third electrode layer disposed on a side surface of the second electrode layer, a second dielectric layer disposed between the second and third electrode layers, a fourth electrode layer disposed on a side surface of the third electrode layer, and a third dielectric layer disposed between the third and fourth electrode layers,
the first interconnection layer further includes a third metal layer covering an upper surface of the third electrode layer, and a fourth metal layer covering an upper surface of the fourth electrode layer, and
the third metal layer includes a third cut-out portion.

5. The printed circuit board according to claim 4, wherein each of the first and third cut-out portions is open in a first direction, and
the second cut-out portion is open in a second direction, different from the first direction.

6. The printed circuit board according to claim 4, wherein the first interconnection layer further includes a first conductor layer penetrating through the second cut-out portion and connected to the first and third metal layers, respectively, a second conductor layer penetrating through the first cut-out portion and connected to the second metal layer, and a third conductor layer penetrating through the third cut-out portion and connected to the second and fourth metal layers, respectively.

7. The printed circuit board according to claim 1, wherein the first interconnection layer further includes a fourth conductor layer connected to an outer surface of the first metal layer.

8. The printed circuit board according to claim 1, wherein each of the first and second metal layers has a ring shape in which a portion thereof is cut off by the first and second cut-out portions.

9. The printed circuit board according to claim 1, wherein an insulating film is further disposed between the first cut-out portion and the first electrode layer, and between the second cut-out portion and the second electrode layer.

10. The printed circuit board according to claim 1, further comprising:
a second insulating layer disposed on an upper surface of the first insulating layer,
wherein at least a portion of the first interconnection layer is embedded in the second insulating layer.

11. The printed circuit board according to claim 1, further comprising:
a second interconnection layer including a fifth metal layer covering a lower surface of the first electrode layer and a sixth metal layer covering a lower surface of the second electrode layer.

12. The printed circuit board according to claim 1, the through-hole has a tapered shape such that a width of an upper end thereof is greater than a width of a lower end thereof in a cross-section.

13. The printed circuit board according to claim 12, further comprising:
a second interconnection layer covering a lower surface of the through-hole,
wherein the first dielectric layer is continuously disposed on the side surface of the first electrode layer and on an upper surface of the second interconnection layer.

14. A printed circuit board, comprising:
a first insulating layer having a through-hole;
a capacitor including a first electrode layer, a first dielectric layer and a second electrode layer sequentially disposed on a side surface of the through-hole; and
first and second metal layers disposed on an upper side of the through-hole and connected to the first and second electrode layers, respectively,
wherein, when viewed from the upper side of the through-hole, each of the first and second metal layers has a shape corresponding to the first and second electrode layers, respectively, and the first and second metal layers include first and second cut-out portions that are open in different directions, respectively.

15. The printed circuit board according to claim 14, further comprising:
a first conductor layer penetrating through the second cut-out portion and connected to the first metal layer; and
a second conductor layer penetrating through the first cut-out portion and connected to the second metal layer.

16. The printed circuit board according to claim 14, wherein the capacitor further includes: a third electrode layer disposed on a side surface of the second electrode layer, a second dielectric layer disposed between the second and third electrode layers, a fourth electrode layer disposed on a side surface of the third electrode layer, and a third dielectric layer disposed between the third and fourth electrode layers.

17. The printed circuit board according to claim 16, further comprising:
a third metal layer disposed on the upper side of the through-hole and connected to the third electrode layer, and including a third cut-out portion;
a fourth metal layer disposed on the upper side of the through-hole and connected to the fourth electrode layer; and
a third conductor layer penetrating through the third cut-out portion and connected to the second and fourth metal layers, respectively,
wherein, when viewed from the upper side of the through-hole, each of the third and fourth metal layers has a shape corresponding to the third and fourth electrode layers, respectively.
